(19) United States
(12) Patent Application Publication
(10) Pub. No.: US 2026/0271756 A1
(43) Pub. Date: Sep. 10, 2026

(54) Interposer

(71) Applicant: TE Connectivity Japan G.K., Kawasaki-shi (JP)

(72) Inventors: Shinichi Hashimoto, Kawasaki-shi (JP); Hirotate Kadobayashi, Kawasaki-shi (JP)

(73) Assignee: TE Connectivity Japan G.K., Kawasaki-shi (JP)

(21) Appl. No.: 19/557,417

(22) Filed: Mar. 5, 2026

(30) Foreign Application Priority Data
Mar. 7, 2025 (JP) 2025-036537

(51) Int. Cl. H10W 70/62; H10W 70/60; H10W 70/654; H10W 90/22

(52) U.S. Cl. CPC H10W 70/644; H10W 70/611; H10W 70/654; H10W 90/22

(57) ABSTRACT

An interposer includes a housing having a plurality of through-holes, a plurality of signal contacts press-fitted into the plurality of through-holes of the housing, the signal contacts are arranged in a plurality of signal contact pairs, and a plurality of ground contacts arranged on both sides of each signal contact pair in each of the first direction and a second direction intersecting the first direction so as to surround the signal contact pair. The signal contacts are adjacent to each other at a predetermined spacing in a first direction that is a width direction of the signal contacts. A width of each ground contact positioned between one signal contact pair and another signal contact pair adjacent to each other in at least the first direction is greater than a width of each of the signal contacts of the signal contact pairs.

### CROSS-REFERENCE TO RELATED APPLICATIONS

This application claims the benefit of the filing date under 35 U.S.C. § 119(a)-(d) of Japanese Patent Application No. 2025-036537, filed on Mar. 7, 2025.

### FIELD OF THE INVENTION

The present disclosure relates to an interposer.

### BACKGROUND OF THE INVENTION

An interposer is typically disposed between two electronic components in order to electrically connect the two electronic components to each other. Such an interposer includes a housing including a plurality of through-holes, and a plurality of contacts inserted into and retained by the respective through-holes.

Each of the contacts included in the interposer includes a base arranged in the through-holes of the housing and retained by the housing, and two contact beams extending from the base to two principal surfaces of the housing, respectively. The plurality of contacts may include a signal contact pair including two signal contacts that are arranged to be adjacent to each other in the width direction of the contacts, which transmit a signal. Efficient improvement in the electrical characteristics of interposers is desired.

### SUMMARY OF THE INVENTION

An interposer includes a housing having a plurality of through-holes, a plurality of signal contacts press-fitted into the plurality of through-holes of the housing, the signal contacts are arranged in a plurality of signal contact pairs, and a plurality of ground contacts arranged on both sides of each signal contact pair in each of the first direction and a second direction intersecting the first direction so as to surround the signal contact pair. The signal contacts are adjacent to each other at a predetermined spacing in a first direction that is a width direction of the signal contacts. A width of each ground contact positioned between one signal contact pair and another signal contact pair adjacent to each other in at least the first direction is greater than a width of each of the signal contacts of the signal contact pairs.

### BRIEF DESCRIPTION OF DRAWINGS

The invention will now be described by way of example with reference to the accompanying figures, of which:

FIG. 1 is a perspective view of an interposer according to an embodiment;

FIG. 2 is a perspective view of an exemplary arrangement of contacts including ground contacts including a characteristic configuration of the interposer of FIG. 1;

FIG. 3 is a perspective view of another exemplary arrangement of the contacts of FIG. 2 including the ground contacts of FIG. 2 including a characteristic configuration of the interposer of FIG. 1;

FIG. 4 is a perspective view of a signal contact of the interposer of FIG. 1;

FIG. 5 is a perspective view of one ground contact of FIG. 2 of the interposer of FIG. 1; and

FIG. 6 is a perspective view of a ground contact according to another embodiment.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

An exemplary embodiment of an interposer 100 will now be described. First, the overall configuration of the interposer 100 of the present disclosure is first described. Subsequently, descriptions of the features of the present disclosure are then described.

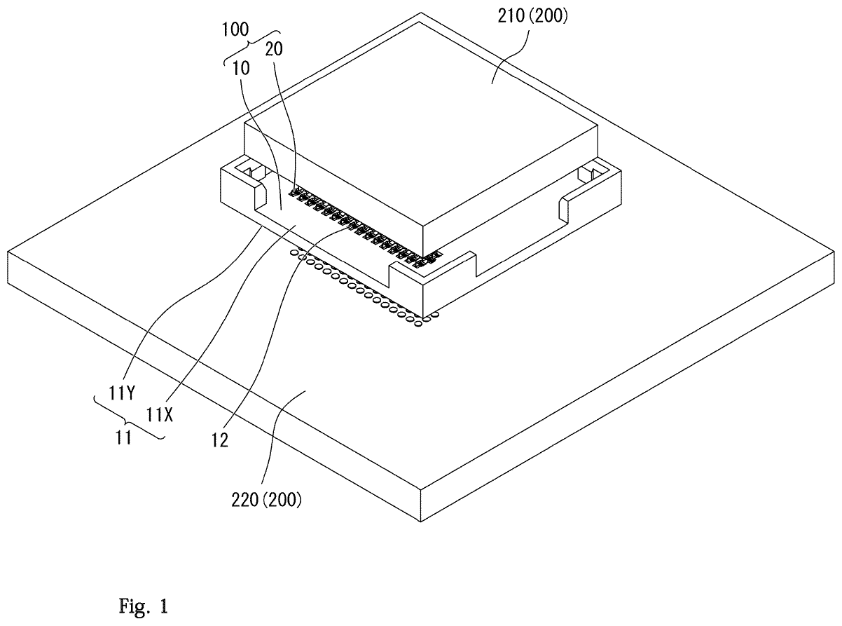

As shown in FIG. 1, the interposer 100 of the present disclosure includes a housing 10 and a plurality of contacts 20.

As shown in FIG. 1, the housing 10 includes a housing body portion 11 and a plurality of through-holes 12. The housing body portion 11 includes two principal surfaces corresponding to each other. The two principal surfaces include a first surface 11X and a second surface 11Y. The plurality of through-holes 12 are pierced between the two principal surfaces (between the first surface 11X and the second surface 11Y).

As shown in FIG. 1, the first surface 11X may be a surface facing a first electronic component 210 of two electronic components 200. The second surface 11Y may be a surface facing a second electronic component 220 of the two electronic components 200. The interposer 100 can be electrically connected to the two electronic components 200.

Examples of the first electronic component 210 described above may include an integrated circuit (IC), without particular limitation. Examples of the second electronic component 220 described above may include a circuit board. In such a case, the interposer 100 of the present disclosure functions as a mediator of signal transmission between the circuit board and the IC.

As shown in FIG. 1, the plurality of through-holes 12 are disposed in a grid pattern in the local portion of housing body portion 11, but without limitation thereto; the plurality of through-holes 12 may be disposed in a grid pattern in a major portion of the housing body portion 11. A material included in the housing 10 may be a material having insulation properties. For example, a thermoplastic resin material can be selected as the material included in the housing 10.

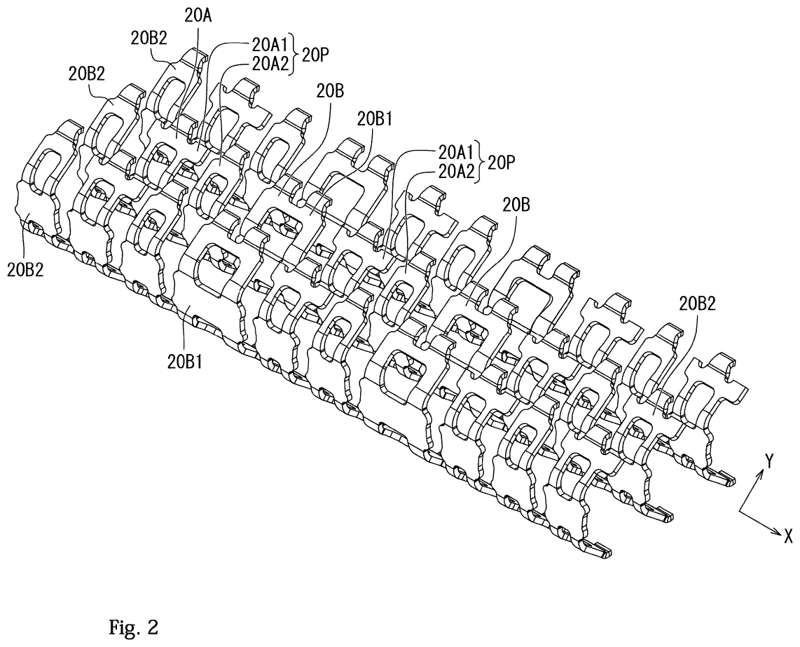

As shown in FIG. 2, the plurality of contacts 20 include signal contacts 20A for transmitting a signal (or also referred to as “signal contacts”) and ground contacts 20B for grounding (or also referred to as “ground contacts”). A material included in the contacts 20 may be a metal material having electrical conductivity. For example, copper can be selected as the material included in the contacts 20.

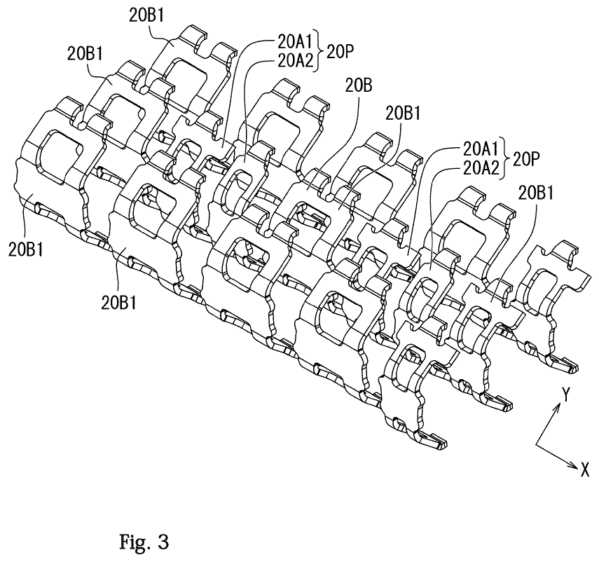

While the shapes of the signal contacts 20A described above may be identical with one another, the signal contacts 20A, as shown in FIGS. 2-3, include first signal contacts 20A1 and second signal contacts 20A2 arranged in directions opposite to each other. Such a first signal contact 20A1 and such a second signal contact 20A2 are included in a signal contact pair 20P, to be adjacent to each other (that is, paired) at a predetermined spacing in the width direction of the signal contacts 20A (hereinafter referred to as “first direction X”).

In descriptions of the signal contacts 20A in the present specification and the drawings, the end of the reference character of the constituent element of each first signal contact 20A1 is denoted by “A1”, and the end of the reference character of the constituent element of each second signal contact 20A2 is denoted by “A2”. The end of the reference character of such a signal contact 20A is denoted by “A” in a case in which such a first signal contact 20A1 and such a second signal contact 20A2 are not classified.

In consideration of the electrical characteristics of the interposer 100 of the present disclosure, the ground contacts 20B are arranged on both sides of each signal contact pair 20P in each of the first direction X corresponding to the width direction of the signal contacts 20A and a second direction Y which is a direction intersecting the first direction X (for example, perpendicular direction) so as to surround the signal contact pair 20P.

In other words, the ground contacts 20B can be arranged in a matrix or grid pattern with respect to a place, in which each signal contact pair 20P is arranged, so as to surround the signal contact pair 20P.

Specifically, the ground contacts 20B can be arranged between one signal contact pair 20P and another signal contact pair 20P adjacent to each other, and outside the signal contact pairs 20P, in the first direction X. In other words, the ground contacts 20B can be arranged on both the sides of each signal contact pair 20P.

Such a first signal contact 20A1 and such a second signal contact 20A2 can be arranged in through-holes 12 adjacent to each other, respectively, among the plurality of through-holes 12 of the housing 10 described above along the width direction of the contacts 20. The ground contacts 20B can be arranged in through-holes 12 positioned in both the sides of each signal contact pair 20P, among the plurality of through-holes 12 of the housing 10 described above.

Each of the plurality of contacts 20 including the signal contacts 20A and the ground contacts 20B described above includes a base that can be press-fitted into each of the through-holes 12 described above. Such press-fitting enables each contact 20 to interlock with the inner wall surface of each through-hole 12 and the contact 20 to be retained in the through-hole 12 when the contact 20 is press-fitted into the through-hole 12.

In addition, each contact 20 can include a first contact beam that extends, from the base, from the first surface 11X of the housing 10 toward the outside, and includes a first contact portion in the leading end of the first contact beam. Furthermore, each contact 20 can include a second contact beam that extends, from the above-described base, from the second surface 11Y of the housing 10 toward the outside, and includes a second contact portion in the leading end of the second contact beam.

In a case in which the first electronic component 210 described above is an IC, connection pads that are formed at positions corresponding to the signal contacts 20A, respectively, and are used for transmitting a signal are disposed on a surface, facing the first surface 11X of the housing 10, of the IC. Installation of the IC enables the first contact portion of each signal contact 20A to come into electrical contact with each connection pad.

In a case in which the second electronic component 220 described above is a circuit board, connection pads that are formed at positions corresponding to the signal contacts 20A, respectively, and are used for transmitting a signal are disposed on a surface, facing the second surface 11Y of the housing 10, of the circuit board. Installation of the interposer 100 of the present disclosure on the circuit board allows the second contact portion 25A of each signal contact 20A to come into electrical contact with each connection pad on the circuit board.

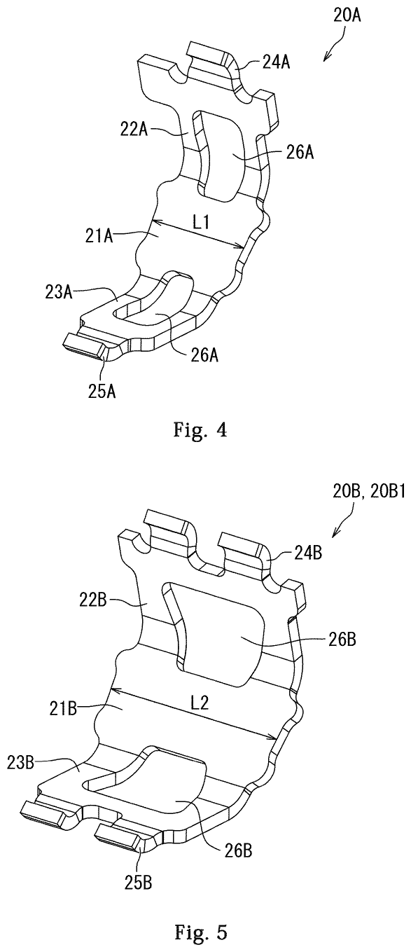

Specifically, as shown in FIG. 4, each signal contact 20A includes a base 21A, a first signal contact beam 22A, and a second signal contact beam 23A. Each signal contact 20A includes two openings 26A formed by the base 21A and the signal contact beams 22A and 23A. Each opening 26A is a spatial region surrounded by the base 21A and each signal contact beam contiguous to the base 21A.

As shown in FIG. 4, the first signal contact beam 22A extends, from the base 21A, from the first surface 11X (also see FIG. 1) of the housing 10 toward the outside, and includes the first contact portion 24A described above in the leading end of the first signal contact beam 22A. The second signal contact beam 23A extends, from the base 21A descried above, from the second surface 11Y (also see FIG. 1) of the housing 10 toward the outside, and includes the second contact portion 25A described above in the leading end of the second signal contact beam 23A.

In the signal contact 20A, the presence of the openings 26A enables the signal contact 20A, particularly the signal contact beams 22A and 23A, to have an elasticity function. The region of the above-described signal contact 20A, coming into contact with each electronic component 200, in a case in which the signal contact 20A has such an elasticity function can be allowed to be larger than that in a case in which the signal contact 20A has no elasticity function. Specifically, the region of the contact portion 24A or 25A of each signal contact beam 22A and 23A, coming into contact with the connection pad described above, can be allowed to be large. As a result, preferred contact between the electronic components 200 and the signal contacts 20A is secured, and electrical connection between the electronic components 200 and the signal contacts 20A can be preferably ensured.

As shown in FIG. 5, each ground contact 20B includes a base 21B, a first ground contact beam 22B, and a second ground contact beam 23B. Each ground contact 20B includes two openings 26B formed by the base 21B and the ground contact beams 22B and 23B. Each opening 26B is a spatial region surrounded by the base 21B and each ground contact beam contiguous to the base 21B.

As shown in FIG. 5, the first ground contact beam 22B extends, from the base 21B, from the first surface 11X (also see FIG. 1) of the housing 10 toward the outside, and includes the first contact portion 24B described above in the leading end of the first ground contact beam 22B. The second ground contact beam 23B extends, from the base 21B described above, from the second surface 11Y (also see FIG. 1) of the housing 10 toward the outside, and includes the second contact portion 25B described above in the leading end of the second ground contact beam 23B.

In the ground contact 20B, the presence of the openings 26B enables the ground contact 20B, particularly the ground contact beams 22B and 23B, to have an elasticity function. The region of the ground contact 20B, coming into contact with, for example, a portion other than the connection pad of each electronic component 200, in a case in which the ground contact 20B has such an elasticity function can be allowed to be larger than that in a case in which the ground contact 20B has no elasticity function. As a result, grounding between the electronic components 200 and the ground contacts 20B can be preferably carried out.

The overall configuration of the interposer 100 of the present disclosure has been described above. The features of the present disclosure will now be described below.

The configuration of each ground contact 20B, as shown in FIG. 5, which is a constituent element of the interposer 100 of the present disclosure is a feature of the interposer 100. Specifically, the present disclosure has a feature in that the width of the ground contact 20B1 positioned between one signal contact pair 20P and another signal contact pair 20P adjacent to each other, among the ground contacts 20B, in at least the above-described first direction X (corresponding to the width direction of the signal contacts 20A) is greater than each of the widths of the signal contacts 20A of the signal contact pairs 20P. Hereinafter, such a ground contact 20B1 of which the width is greater than each of the widths of the signal contacts 20A is referred to as “first ground contact 20B1” for convenience.

Separation between such signal contact pairs 20P adjacent to each other at a predetermined spacing is required for avoiding electrical interference between the signal contact pairs 20P adjacent to each other to improve the electrical characteristics of the interposer 100. In this regard, for example, in the case of using ground contacts 20B of which each of the widths is equivalent to each of the widths of signal contacts 20A, arrangement of a plurality of ground contacts 20B between signal contact pairs 20P adjacent to each other in the first direction X may be required.

In contrast, in accordance with the features described above, each first ground contact 20B1 is a ground contact 20B of which the width L2, as shown in FIG. 5, is greater than the width L1, as shown in FIG. 4, of each signal contact 20A, and therefore, such signal contact pairs 20P adjacent to each other can be separated by such a single first ground contact 20B1. As used herein, “width L1 of signal contact 20A” and “width L2 of first ground contact 20B1” refer to the widths of the predetermined corresponding places of the respective contacts 20.

In other words, the signal contact pairs 20P adjacent to each other can be separated by the single ground contact 20B1 even in a case in which the arrangement of a plurality of ground contacts between the signal contact pairs 20P adjacent to each other for improvement in the electrical characteristics of the interposer 100 is not performed. Therefore, in accordance with the features described above, the electrical characteristics of the interposer 100 can be efficiently improved.

Since the arrangement of a plurality of ground contacts 20B between the signal contact pairs 20P adjacent to each other is not necessarily required, more signal contact pairs 20P can be arranged in a predetermined range than those in a pattern in which the plurality of ground contacts 20B are arranged. The arrangement of such many signal contact pairs 20P enables signal transmission between two electronic components 200 to be more efficiently performed.

It is preferable to alternately arrange the plurality of signal contact pairs 20P and the first ground contacts 20B1 in the first direction X described above. In other words, each first ground contact 20B1 can be arranged between such signal contact pairs 20P adjacent to each other. In accordance with such arrangement, such signal contact pairs 20P adjacent to each other can be separated by a single ground contact 20B1. Therefore, the electrical characteristics of the interposer 100 can be more efficiently improved.

As shown in FIG. 3, such a first ground contact 20B1 can be arranged on at least one side of such a signal contact pair 20P in the second direction Y described above on the precondition that the features of the present disclosure are secured. In such a case, the number of the through-holes 12 of the housing body portion 11 in a predetermined range can be decreased.

All the ground contacts 20B used in the interposer 100 of the present disclosure are preferably the first ground contacts 20B1 described above. In such a case, the number of the types of the ground contacts 20B can be limited to one, and therefore, the efficiency of producing the interposer 100 can be enhanced as a whole.

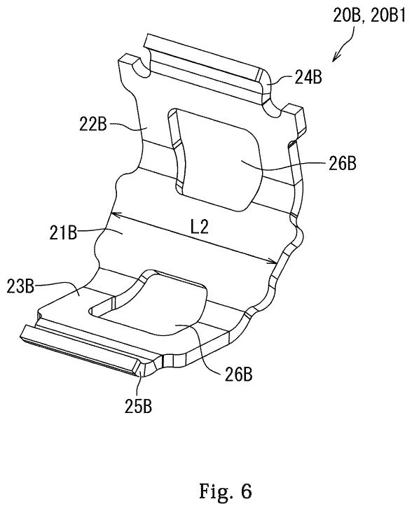

An exemplary embodiment of another first ground contact 20B1 will now be described with reference to FIG. 6. The first ground contact 20B1, as shown in FIG. 5, having another shape can also be used on the precondition that the features of the present disclosure are secured. Specifically, the shape in which the contact portions 24B and 25B formed in the leading ends are contiguous to one another, respectively, in the width direction of the ground contacts 20B1 is enabled to be formed so that relatively larger grounding regions than those shown in FIG. 5 can be secured.

A second ground contact 20B2, as shown in FIG. 2, having the same shape as the shape of each of the signal contacts 20A and a width that is relatively smaller than the width of each of the first ground contacts 20B1 can be used as the ground contact 20B at the outermost position in a predetermined region in the first direction X, except the ground contacts 20B arranged between the signal contact pairs 20P adjacent to each other.

In accordance with such a configuration, the overall width of the interposer 100 can be decreased by substituting the second ground contact 20B2 for the ground contact 20B at the outermost position. The number of produced first ground contacts 20B1 having specific shapes can be reduced in comparison with the signal contacts 20A. As a result, the efficiency of producing the interposer 100 can be enhanced as a whole.

The interposer 100 of the present disclosure is not limited to the embodiments described above. Modifications thereto may be made within the scope of the present disclosure, as appropriate.

Industrial applicability of the interposer 100 is as follows: the interposer 100 of the present disclosure is used for electrically connecting two electronic components 200.

1. An interposer, comprising:
a housing including a plurality of through-holes;
a plurality of signal contacts press-fitted into the plurality of through-holes of the housing, the signal contacts are arranged in a plurality of signal contact pairs, the signal contacts are adjacent to each other at a predetermined spacing in a first direction that is a width direction of the signal contacts; and
a plurality of ground contacts arranged on both sides of each signal contact pair in each of the first direction and a second direction intersecting the first direction so as to surround the signal contact pair, a width of each ground contact positioned between one signal contact pair and another signal contact pair adjacent to each other in at least the first direction is greater than a width of each of the signal contacts of the signal contact pairs.

2. The interposer of claim 1, wherein one of the ground contacts having the width greater than the width of each of the signal contacts is disposed between one signal contact pair and another signal contact pair adjacent to each other.

3. The interposer of claim 1, wherein the signal contact pairs and the ground contacts each having the width greater than the width of each of the signal contacts are alternately arranged in the first direction.

4. The interposer of claim 1, wherein each of the ground contacts having the width greater than the width of each of the signal contacts is arranged between the signal contact pairs adjacent to each other in the first direction.

5. The interposer of claim 1, wherein each of the ground contacts having the width greater than the width of each of the signal contacts is arranged on at least one side of each of the signal contact pairs in the second direction.

6. An interposer, comprising:
a housing having a plurality of through-holes, each through-hole extends through the housing; and
a plurality of contacts including a plurality of signal contact pairs and a plurality of ground contacts, the plurality of ground contacts include a plurality of first ground contacts, each signal contact pair includes two signal contacts press-fitted into the plurality of through-holes, the signal contacts are adjacent to each other in a width direction of the signal contacts, the ground contacts are arranged on both sides of each signal contact pair so as to surround the signal contact pair, a width of each first ground contact between one signal contact pair and another signal contact pair adjacent to each other is greater than a width of each of the signal contacts of the adjacent signal contact pairs.

7. The interposer of claim 6, wherein one first ground contact is disposed between one signal contact pair and another signal contact pair adjacent to each other.

8. The interposer of claim 6, wherein the signal contact pairs and the first ground contacts are alternately arranged in the width direction.

9. The interposer of claim 6, wherein each first ground contact is arranged between the signal contact pairs adjacent to each other in the width direction.

10. The interposer of claim 6, wherein each first ground contact is arranged on at least one side of each of the signal contact pairs in a second direction intersecting the width direction.

11. The interposer of claim 6, wherein the plurality of ground contacts include a plurality of second ground contacts, each second ground contact has a same width as each signal contact.

12. The interposer of claim 11, wherein each first ground contact is arranged between the signal contact pairs adjacent to each other in the width direction, each second ground contact is arranged adjacent to only one signal contact in the width direction.

13. The interposer of claim 11, wherein each first ground contact is arranged between the signal contact pairs adjacent to each other in the width direction, each second ground contact is arranged at an outermost position adjacent to only one signal contact pair.

14. The interposer of claim 11, wherein each second ground contact has a same shape as a shape of each signal contact.

15. The interposer of claim 6, wherein each signal contact includes a base, a first signal contact beam, a second signal contact beam, and two openings defined by the base and the signal contact beams, each opening is surrounded by the base and each signal contact beam contiguous to the base.

16. The interposer of claim 15, wherein the first signal contact beam, of a signal contact press press-fitted into the plurality of through-holes, extends from a first surface of the housing, and includes a first contact portion in a leading end of the first signal contact beam, and the second signal contact beam, of the signal contact press press-fitted into the plurality of through-holes, extends from a second surface of the housing, and includes a second contact portion in a leading end of the second signal contact beam.

17. The interposer of claim 6, wherein each ground contact includes a base, a first ground contact beam, and a second ground contact beam, and two openings defined by the base and the ground contact beams, each opening is surrounded by the base and each ground contact beam contiguous to the base.

18. The interposer of claim 17, wherein the first ground contact beam includes a first contact portion in a leading end of the first ground contact beam, and the second ground contact beam includes a second contact portion in a leading end of the second ground contact beam.

19. The interposer of claim 17, wherein the first ground contact beam includes a pair of first contact portions, and the second ground contact beam includes a pair of second contact portions.
